(19) United States
(12) Patent Application Publication
(10) Pub. No.: US 2004/0056269 A1
(43) Pub. Date: Mar. 25, 2004

(54) PASSIVATION STRUCTURE

(76) Inventor: Kuang-Jung Chen, Taipei City (TW)

Correspondence Address: NAIPO (NORTH AMERICA INTERNATIONAL PATENT OFFICE), P.O. BOX 506, MERRIFIELD, VA, 22116, US

(21) Appl. No.: 10/249,994

(22) Filed: May 26, 2003

(30) Foreign Application Priority Data
Jul. 25, 2002 (TW) 091116648

(51) Int. Cl. H01L 33/00

(52) U.S. Cl. 257/100; 257/99; 257/103

(57) ABSTRACT

A passivation structure capping an electrical device disposed on a substrate is introduced. The passivation structure includes a first diamond-like carbon film covering a top surface and the sidewall of the electrical device and the surface of the substrate, a buffer layer positioned on the first diamond-like carbon film, and a second diamond-like carbon film positioned on the buffer layer. Part of the second diamond-like carbon film covers the first diamond-like carbon film directly to form a cyclic structure.

### BACKGROUND OF INVENTION

1. Field of the Invention

The present invention relates to a passivation structure, and more particularly, to a passivation structure comprising a cyclic structure composed of a diamond-like carbon film to resolve the heat issues of OLED devices.

2. Description of the Prior Art

The progress of science and technology has led to organic materials being well applied to all kinds of electrical devices. For example, organic light-emitting displays (OLEDs), which are formed by using organic materials, have the advantages of simpler structures, excellent operating temperature, high contrast, and a wide viewing angle, and have the beneficial characteristics of light-emitting diodes (LEDs), such as rectification and luminosity, so as to be used extensively in the field of display devices. Since the OLED uses luminous devices formed of organic materials to provide a light source, the OLED is very sensitive to the moisture. Once the organic light-emitting devices are exposed in the moisture, the cathode thereon may be oxidized and the interface of organic compounds may be peeled. This leads to dark spots being generated in the luminous devices, which deteriorates the brightness and the lifetime of the display devices. As a result, the package material used to package the electrical devices not only needs high anti-abrasiveness and thermal conductivity, but also requires low moisture permeability to prevent the organic materials from being exposed in the external environment effectively and to improve the lifetime of the electrical devices.

For example, in the conventional package process of display devices, a sealing agent made of polymer materials is often used to combine the container, which is composed of a metal or glass material, with the substrate and desiccants and dry nitrogen are filled into the empty region there between. However, this package structure can be only applied to the display devices with metal or glass substrates, but cannot be used in packaging those with the flexible substrates. In addition, the metal container has disadvantages of having a heavy weight, and being oxidized easily. In the fabricating process, the metal container also has disadvantages of pealing off from the glass materials easily and having the requirement of a high degree of flatness. The glass container has the disadvantages of having heavy weight, cracking easily, and pealing off easily due to stress differences. Moreover, most of the sealing agents composed of polymer materials lack adequate protection from moisture. As a result, although the electrical devices are packaged, the moisture of the external environment still permeates into the packaged device gradually and erodes the display devices so as to deteriorate the display effect and decrease the lifetime of the display devices.

In order to solve the above-mentioned problems of the metal or glass container, a new passivation process that utilizes films to encapsulate the protected devices was developed. Please refer to FIG. 1, which is a cross-sectional diagram of a passivation structure 16 disclosed in U.S. Pat. No. 5,811,177. As shown in FIG. 1, an OLED 10 mainly comprises a substrate 12, a display unit 14 positioned on the substrate 12, and a passivation structure 16 covering the display unit 14 and the substrate 12. The display unit 14 is composed of a plurality of pixels and further comprises a driving circuit (not shown) disposed on the substrate 12 for driving the pixels to display. The passivation structure 16, which is a multiple film structure, comprises a metal layer 18, a buffer layer 20, a thermal coefficient matching layer 22, a low permeability layer 24, and a sealing layer 26 stacked on the display unit 14 in sequence for protecting the display unit 14.

Furthermore, another passivation structure which utilizes a metal layer, inorganic materials and hydrophobic polymer materials is disclosed in U.S. Pat. No. 5,952,778. Another moisture-proof multi-layer structure is disclosed in Chinese Taipei Patent 379,531 to improve the above-mentioned problem. The structure includes a moisture-adsorbing resin layer, an adhesive layer, and a transparent resin layer and covers an electroluminescent device to prevent the electroluminescent device from moistening and oxidizing.

As mentioned above, the conventional passivation structure utilizes inorganic ceramic materials, metal materials and polymer materials stacking on display units as a passivation structure to prevent electrode materials or organic materials in the display device from being eroded or oxidized by the moisture and oxygen in the external environment. Normally, some moisture sensitive electrical devices, such as the OLED, requires a passivation whose permeability is less than 0.05 g/m² day. Thus, most of the conventional passivation structures are composed of more than five stacked layers to meet the permeability requirement. However, the heat dispersion ability cannot be satisfied in the aforementioned structures. In other words, although the multi-layer structure can provide a better effect on moisture protection, there is the disadvantage of low heat dispersion ability and a complicated fabricating process which leads to a high fabrication cost and long fabricating time. Thus, it is important to develop a new passivation structure to solve the aforementioned problem.

### SUMMARY OF INVENTION

It is therefore a primary objective of the claimed invention to provide a passivation structure which comprises a cyclic structure composed of a diamond-like carbon film to solve the problem mentioned above.

In a preferred embodiment of the claimed invention, a passivation structure capping an electrical device disposed on a substrate is introduced. The passivation structure comprises a first diamond-like carbon film covering a top surface and the sidewall of the electrical device and the surface of the substrate, a buffer layer positioned on the first diamond-like carbon film, and a second diamond-like carbon film positioned on the buffer layer. Part of the second diamond-like carbon film covers the first diamond-like carbon film directly to form a cyclic structure.

It is an advantage of the claimed invention that the present passivation structure utilizes a material character of the diamond-like carbon film to obtain a good anti-abrasiveness and a low permeability and uses the formed cyclic structure to provide a high thermal conductivity and improve the lifetime of the protected electrical device in advance.

These and other objectives of the claimed invention will not doubt become obvious to those of ordinary skill in the art after reading the following detailed description of the preferred embodiment, which is illustrated in the various figures and drawings.

### BRIEF DESCRIPTION OF DRAWINGS

FIG. 1 is a schematic diagram of a passivation structure according to prior art.

FIG. 2 is a-schematic diagram of a passivation structure according to the present invention.

FIG. 3 is a local amplified diagram of the passivation structure shown in FIG. 2.

FIG. 4 is a top view of the passivation structure of the present invention.

FIG. 5 shows the moisture permeability of DLC films and silicon nitride layers.

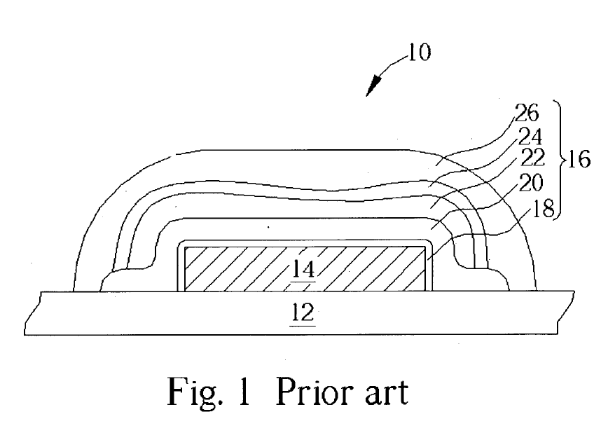

### DETAILED DESCRIPTION

The present invention discloses a passivation of an electrical device. In order to show the difference between the passivation structure of the present invention and that of the prior art, an OLED is illustrated in the following to describe the passivation structure in the present invention. It is important that the present invention is not limited in the passivation structure of an OLED, but can be applied to other electrical devices, such as an LCD or semiconductor devices.

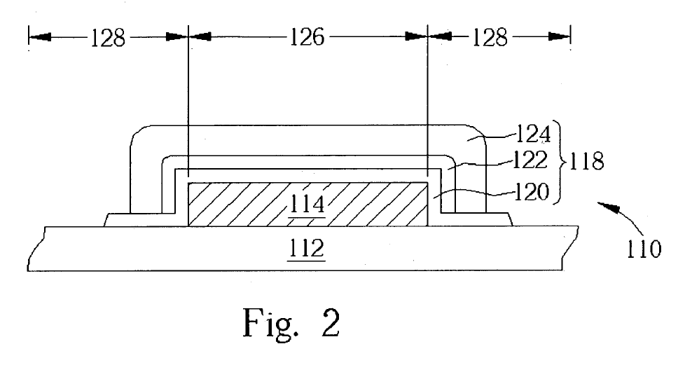

Please refer to FIG. 2, which is a cross-sectional diagram of a passivation structure of an OLED in a preferred embodiment of the present invention. As shown in FIG. 2, the OLED 110 comprises a substrate 112 and a display unit 114 positioned on the surface of the substrate 112 to define a display region 126, and a peripheral region 128. In addition, the OLED 110 further comprises a passivation structure 118 covering the display unit 118 to prevent the display unit from being exposed to the external atmosphere.

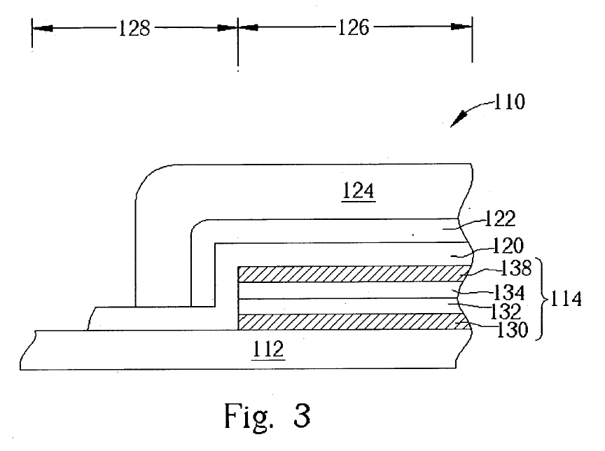

Please refer to FIG. 3 of a local amplified diagram of the passivation structure 118 of FIG. 2. As shown in FIG. 3, the display unit 114 is composed of a plurality of pixels. Each pixel, which is a multi-layer. structure, comprises a conductive layer 130, a luminous layer 132, a metal layer 134, and a conductive layer 138 stacked on the substrate 112 in sequence. In the preferred embodiment of the present invention, the substrate 112 is a glass substrate. The conductive layers 130 and 138 are composed of indium tin oxide (ITO) or indium zinc oxide (IZO). The luminous layer 132 is composed of organic materials, such as an organic luminous layer composed of conjugated polymers. The metal layer 134 comprises alloys of Al—Mg, Al—Li, or Al—LiF.

The passivation structure 118 comprises a first diamond-like carbon (DLC) film 120, a buffer layer 122 and a second DLC film stacked in sequence. The first DLC film 120 covers a top surface and sidewalls of the display unit 114 and the substrate 112 so that the display unit 114 can be fully enclosed between the substrate 112 and the passivation structure 118. In the preferred embodiment of the present invention, the first DLC film 120 and the second DLC film 124 are both formed in a plasma-enhanced chemical vapor deposition (PECVD) process with a thickness about 10 to 50000 angstroms. The buffer layer 122 comprises solvent type or non-solvent type thermal curable materials, materials composed of diamond-like carbon layer and polymers, UV curable materials, or thermal evaporation polymer materials. The main function of the buffer layer 122 is for reducing a stress between the first DLC film 120 and the second DLC film 124 and preventing the first DLC film 120 and the second DLC film 124 from cracking

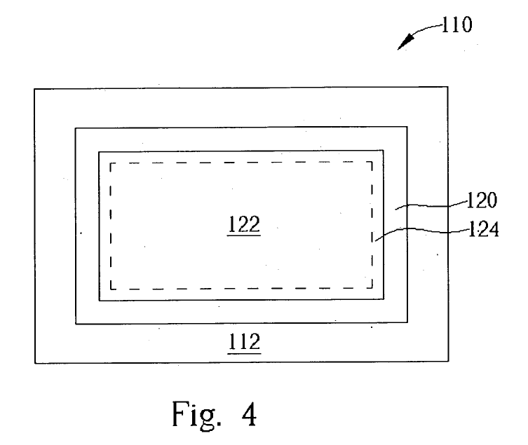

Please refer to FIG. 3 and FIG. 4. FIG. 4 is a top view of the passivation structure 118 of the present invention. It is clearly shown that an area covered by the buffer layer 122, is less than that covered by the first DLC film 120 and less than that covered by the second DLC layer 124. As a result, the second DLC film 124 covers parts of the first DLC film 120 directly so that a cyclic structure is formed of the first DLC film 120 and the second DLC film 124 thereby. In addition, the cyclic structure is located on the peripheral region 128 and therefore has no effect on the permeability of the passivation structure 1129 above the display region 126.

The passivation structure 118 of the present invention uses the DLC film as a major package material. The DLC film, which is a carbon film bonded in a state between sp³, such as a diamond, and sp², such as graphite, is formed by a magnetically sputtering method, an ion plating method, an arc ion plating method or the PECVD process as shown in the aforementioned preferred embodiment. Furthermore, by controlling the process parameter or using additional dopants, the formed DLC films can have different features, such as a soft polymer-like film with very small stress or an amorphous DLC film with a high hardness. In the present invention, a DLC film with low permeability is used to achieve the purpose of avoiding moisture penetration.

Nakahigashi et al. (U.S. Pat. No. 6,136,386) disclosed a method of coating polymer or glass objects with carbon films. In Nakahigashis disclosure, a DLC film is deposited on a plastic film by a CVD process to suppress the transmittance of the moisture and oxygen gas.

As shown in FIG. 5, the DLC filmdeposited on the plastic film can reduce the transmittance of the moisture and oxygen gas effectively. Comparing with the original plastic film, the plastic film coated with the DLC film can reduce the moisture permeability to 1/14 and the oxygen permeability to 1/12.

In the Japan Industrial Material on July 2000 (page 97, Vol. 48 No.6), it also disclosed that depositing a DLC film with a thickness about 10 to 100 nm on a PET film can reduce the oxygen permeability to 1/30 of the original.

Besides the low permeability, the DLC film also has the characteristic of high hardness (3000-5000 kg/mm²), high acid and base resistances, a high dielectric coefficient, high anti-abrasiveness, and high smoothness of the surface. In addition, the thermal conductivity of the DLC film, which is about 1100 W/cm-K, is much higher than the conventional package materials, such as an aluminum nitride (170 W/cm-k), aluminum oxide (28 W/cm-k), silicon nitride (25 W/cm-k), titanic oxide (10.4 W/cm-k), or silicon oxide (0.02 W/cm-k). Furthermore, the-passivation structure of the present invention comprises the cyclic structure formed of the first DLC film 120 and the second DLC film 124, which can fully develop the high thermal conductivity of the DLC film. In other words, when the display unit 114 generates a lot of heat when operating, the heat is rapidly transferred from the first DLC film 120, which is the most inner layer of the passivation structure 118, to the second DLC film 124, which is the most outer layer of the passivation structure 118, through the cyclic structure. Then, the heat is dispersed to the external atmosphere rapidly from the second DLC film 124, which contacts with air directly, so as to improve the heat dissipation of the display device 110 effectively and solve the problem in the conventional OLED devices, which utilize a multi-layer structure to obtain enough waterproof ability but decrease the heat dissipation of the display units.

It is important that the passivation structure in the aforementioned embodiment is applied to the field of OLED packaging. However, the present invention is not limited in the OLED field. For those skilled in the art, the present invention can be further applied to all kinds of electrical devices which need a passivation structure of high anti-abrasiveness, low moisture permeability, or high thermal dissipation according to the aforementioned descriptions and drawings so as to improve the lifetime of the electrical devices.

In contrast with the prior art, which uses inorganic materials or the ceramics materials, the present invention uses the DLC film as a major package material so as to obtain a better anti-abrasiveness, a higher thermal dissipating ability, and a lower moisture permeability. Therefore, the passivation structure of the present invention can prevent the electrode materials or the organic materials in the electrical devices from contacting the external atmosphere, which leads to deterioration of the lifetime the electrical devices. In addition, the first DLC film and the second DLC film contact directly and form a cyclic structure thereby. As a result, the DLC film in the top layer of the passivation structure not only provide a high anti-abrasiveness to protect the packaged electrical device, but also use the high thermal conductivity of the DLC film to dissipate the generated heat rapidly from the inner DLC film through the cyclic structure to the external atmosphere. Therefore, the thermal dissipating ability of the passivation structure can be increased effectively so that the stability and lifetime of the electrical devices are both improved in advance.

Those skilled in the art will readily observe that numerous modifications and alterations of the invention may be made while retaining the teachings of the invention. Accordingly, the above disclosure should be construed as limited only by the metes and bounds of appended claims.

What is claimed is:

1. A passivation structure covering an electrical device positioned a the substrate, the passivation structure comprising:
a first diamond-like carbon (DLC) film covering a top surface and sidewalls of the electrical device and the substrate surface as a bottom layer of the passivation structure;
a buffer layer disposed on the first diamond-like carbon film;
a second diamond-like carbon film covering the buffer layer and parts of the first diamond-like carbon film as a top layer of the passivation structure;
wherein the first diamond-like carbon film and the second diamond-like carbon film form a cyclic structure.

2. The passivation structure of the claim 1 wherein the thickness of first diamond-like carbon film and the thickness of the second diamond-like carbon film are each about 10 to 50000 angstroms.

3. The passivation structure of the claim 1 wherein the buffer layer comprises solvent type or non-solvent type thermal curable materials or UV curable materials.

4. The passivation structure of the claim 1 wherein the buffer layer comprises thermal evaporation polymer material.

5. The passivation structure of the claim 1 wherein the buffer layer comprises materials composed of diamond-like carbon layer and polymers.

6. The passivation structure of the claim 1 wherein the buffer layer comprises materials composed of inorganic materials and polymers.

7. The passivation structure of the claim 1 wherein the first diamond-like carbon film, which functions as a heat conductor, transfers the heat generated from the electrical device to the second diamond-like carbon film and the second diamond-like carbon film provides functions of heat dissipation and protection.

8. The passivation structure of the claim 1 wherein the cyclic structure is used as a heat dissipating structure of the electrical device.

9. The passivation structure of the claim 1 wherein the electrical device is a display unit.

10. The passivation structure of the claim 9 wherein the display unit is an organic light emitting display (OLED) unit.

11. The passivation structure of the claim 10 wherein the organic light emitting display unit comprises a conjugated polymer layer, one conductive layer positioned above the conjugated polymer layer, and another conductive layer positioned under the conjugated polymer layer.

12. The passivation structure of the claim 1 wherein an area covered by the first diamond-like carbon film is larger than an area covered by the buffer layer.

13. The passivation structure of the claim 1 wherein an area covered by the second diamond-like carbon film is larger than an area covered by the buffer layer.
